(19) United States
(12) Patent Application Publication
(10) Pub. No.: US 2022/0006264 A1
(43) Pub. Date: Jan. 6, 2022

(54) SEMICONDUCTOR DEVICE AND FABRICATION METHOD

(71) Applicant: UCL Business PLC, London (GB)

(72) Inventors: Mingchu TANG, London (GB); Mengya LIAO, London (GB); Siming CHEN, London (GB); Jiang WU, London (GB); Alwyn SEEDS, London (GB); Huiyun LIU, London (GB)

(21) Appl. No.: 17/374,392

(22) Filed: Jul. 13, 2021

Related U.S. Application Data
(63) Continuation of application No. 16/467,626, filed on Jun. 7, 2019, now abandoned.

(30) Foreign Application Priority Data
Dec. 7, 2016 (GB) 1620826.6

(51) Int. Cl. H01S 5/34; H01S 5/02; H01S 5/343

(52) U.S. Cl. CPC H01S 5/3425; H01S 5/021; H01S 5/341; H01S 5/34313; H01S 2301/173; H01S 5/3412; H01S 2304/02; H01S 2304/04; H01S 5/0218

(57) ABSTRACT

A semiconductor device comprising a nominally or exactly or equivalent orientation silicon substrate on which is grown directly a <100 nm thick nucleation layer (NL) of a III-V compound semiconductor, other than GaP, followed by a buffer layer of the same compound, formed directly on the NL, optionally followed by further III-V semiconductor layers, followed by at least one layer containing III-V compound semiconductor quantum dots, optionally followed by further III-V semiconductor layers. The NL reduces the formation and propagation of defects from the interface with the silicon, and the resilience of quantum dot structures to dislocations enables lasers and other semiconductor devices of improved performance to be realized by direct epitaxy on nominally or exactly or equivalent orientation silicon.

### RELATED APPLICATIONS

The present application is a continuation of U.S. application Ser. No. 16/467,626, filed Jun. 7, 2019 which is a National Phase of International Application Number PCT/GB2017/053686, filed Dec. 7, 2017, and claims priority to Great Britain Application Number 1620826.6, filed Dec. 7, 2016, the disclosure of which is hereby incorporated by reference herein in its entirety.

### FIELD

The present disclosure relates to a semiconductor device and method of fabrication thereof relating to III-V compounds grown on silicon (Si).

### BACKGROUND

The realization of semiconductor laser diodes on a Si platform will enable the fabrication of complex optoelectronic circuits, which will permit the creation of chip-to-chip, rack-to-rack and system-to-system optical communications. Although in the last 30 years great effort has been devoted to Si-based light generation and modulation technologies, lasers grown directly on Si substrates are still considered to be one of the greatest challenges to be realized among all Si photonics components and have massive potential for applications if successful. Due to the indirect band structure of Si and Ge, efficient radiative recombination processes for Ge and Si emitters are insignificant compared to non-radiative recombination. Direct bandgap III-V compounds have robust photonic properties for semiconductor emitters in a wide range of photonic applications. Direct epitaxial growth of III-V compound semiconductor materials, such as GaAs on Si substrates is one of the most promising candidates for the fabrication of electrically pumped lasing sources on a Si platform, because of its potential for the realization of photonic integrated circuits by combining the optoelectronic properties of III-V with Si very large scale integration (VLSI) microelectronic technology. The heteroepitaxial technology could also provide III-V compound semiconductor photonic circuits with large-area, low-cost and lightweight substrates with high mechanical strength and high thermal conductivity, which can accommodate associated electronic functions.

The most severe problem remaining to be solved in the monolithic integration of GaAs and other III-V compounds on Si substrate is the large material dissimilarity between III-V and Group IV materials, including lattice mismatch, thermal expansion coefficient differences, and polar versus nonpolar surfaces. These differences between III-V and Group IV materials tend to produce various types of defects—antiphase boundaries (APBs), threading dislocations (TDs), and microcracks—which all generate nonradiative recombination centers and dramatically undermine the promise of III-V materials. Reducing the defect density within the GaAs buffer layer on Si substrates is critical for successful integration of III-Vs-based photonic components with Si microelectronic circuits. Moreover, recent studies have shown that III-V nanosized crystals—quantum dots (QDs)—are a better alternative to quantum wells for building III-V lasing devices on a Si platform due to their unique advantages, such as lower threshold current density (Jth), temperature-insensitive operation above room temperature (RT), and lower sensitivity to defects.

We have shown in the patent, (U.S. Pat. No. 9,343,874 (B2)) that the use of an AlAs nucleation layer prior to the growth of the III-V layer on Si can enable a successful electrically pumped laser to be grown on Si. We have also shown in patent (U.S. Pat. No. 9,401,404 (B2)) that the use of Ge on Si as the substrate upon which the III-V layer is grown can enable a successful electrically pumped laser to be grown on Si.

Both approaches mentioned above have used offcut substrates, i.e. Si (001) or equivalent orientation wafers with an offcut of 4° to the [110] plane and Ge (001) wafers with an offcut of 6° to the [110] plane, in order to prevent the formation of antiphase domains (APDs) while growing polar III-V materials on non-polar group-IV substrates. Although this approach is successful in overcoming the APD problem, it has the disadvantage of not being readily compatible with standard microelectronics fabrication where wafers with nominally (001) silicon substrates are used. In general, the nominal silicon substrates, i.e., the so-called “exact” (001) silicon substrates with a miscut angle less than 0.5°, have been used in standard microelectronics fabrication. Recently, optically pumped microcavity lasers have been demonstrated on exact (001) Si substrates by nanopatterning the Si (Wan, Y., Li, Q., Liu, A. Y., Gossard, A. C., Bowers, J. E., Hu, E. L., Lau, K. M. Optically pumped 1.3 pm room temperature InAs quantum-dot microdisk lasers directly grown on (001) silicon. Optics Letters, 41, (2016)) and recently an electrically pumped laser has been demonstrated by growth on a GaP/Si (001) template (Liu et al, Electrically pumped continuous wave III-V quantum dot lasers epitaxially grown on exact GaP/Si (001)). Neither approach uses substrates that are standard for microelectronic fabrication and the electrically pumped laser threshold current density is over 800 A/cm², which is a much higher value than is achieved in our previous work on offcut substrates (U.S. Pat. Nos. 9,343,874 and U.S. 9,401,404) The high threshold current density restricts the application of these lasers in practical optical interconnects. The present disclosure seeks to alleviate, at least partially, some or any of the above problems.

### SUMMARY

In this application, the electrically pumped silicon-based InAs/GaAs quantum-dot laser has been demonstrated by the use of direct grown GaAs on nominal (001) Si substrates. RT continuous wave (cw) lasing at ˜1.3 μm with threshold current density of 425 A/cm² and output power of 43 mW at room temperature has been achieved. Under pulsed operation, we show significantly improved device performance including lasing operation at device temperatures exceeding 100° C. and output from a single facet exceeding 130 mW at room temperature by limiting self-heating.

### BRIEF DESCRIPTION OF THE DRAWINGS

Further features, characteristics, and aspect of the present disclosure are described in the following figures. These serve for easy understanding of the disclosure. In the figures:

FIG. 1 shows a schematic of the layer structure grown on Si (001) substrates according to at least one embodiment.

FIG. 2 shows a typical 5×5 μm² AFM image of 400 nm GaAs grown on Si (001) substrate by MOCVD showing an APG-free GaAs layer according to at least one embodiment.

FIG. 3 shows a graph of LIV characteristics for a 25 μm×3000 μm InAS/GaAS QD laser grown on a silicon (001) substrate under cw operation at room temperature according to at least one embodiment.

FIG. 4 shows a graph of CW lasing spectrum for InAs/GaAs QD laser grown on Si (001) substrate at room temperature according to at least one embodiment.

FIG. 5 shows a graph of CW light output power versus current density for InAs/GaAs QD laser on silicon (001) at various heatsink temperatures according to at least one embodiment.

FIG. 6 shows a graph of L-I characteristic of QD laser grown on Si (001) under pulsed operation of 1% duty-cycle and 1 μs pulse-width according to at least one embodiment.

FIG. 7 shows a graph of light output power versus current density for InAs/GaAs QD laser on silicon (001) at various heatsink temperatures under pulsed operation according to at least one embodiment.

### DETAILED DESCRIPTION

Embodiments of the disclosure will now be described, by way of example only, with reference to the accompanying drawings in which:

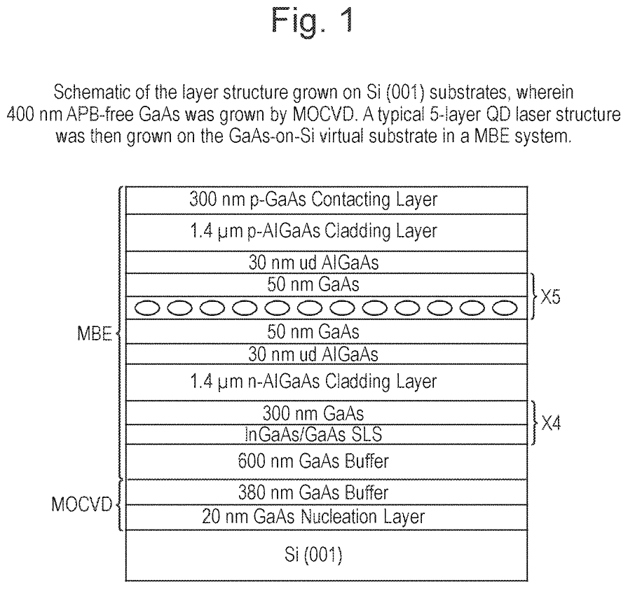

In one exemplary embodiment of the present disclosure, as shown in FIG. 1, a 20 nm thick GaAs nucleation layer is first grown directly upon the nominal (001) or equivalent orientation Si wafer, followed by a 380 nm thick GaAs buffer layer, both layers being grown by metal-organic chemical vapour deposition (MOCVD). The InAs/GaAs QD laser structure is then grown on the optimal GaAs-on-silicon (001) by molecular beam epitaxy (MBE). Epitaxy was then performed in the following order: a 600 nm GaAs buffer layer, InGaAs/GaAs dislocation filter layers, and five layers of InAs/GaAs dot in a well (DWELL) structures separated by 50 nm GaAs spacers in the middle of a 140 nm undoped GaAs waveguide between 1.4 μm n-type lower and p-type upper Al_{0.4}Ga_{0.6}As cladding layers. Finally, a 300 nm p-type GaAs contact layer was grown.

The nucleation layer is different from the III-V compound buffer layer. Although the nucleation layer (NL) and the buffer layer comprise the same material, they use different growth parameters, including but not limited to substrate temperature and gas flow rates during the manufacturing process. In one example, for the GaAs N, the wafer was cooled to a low temperature of 400-500° C. (measured by optical pyrometer) and the first GaAs layer of 20 nm thickness was deposited, then the wafer was reheated to conventional growth temperature of 600-700° C. to grow a high quality GaAs buffer layer of 380 nm thickness. The typical V/III ratio is in the range of 5-30.

Other growth conditions leading to the creation of a GaAs buffer layer with minimum defect density can be used.

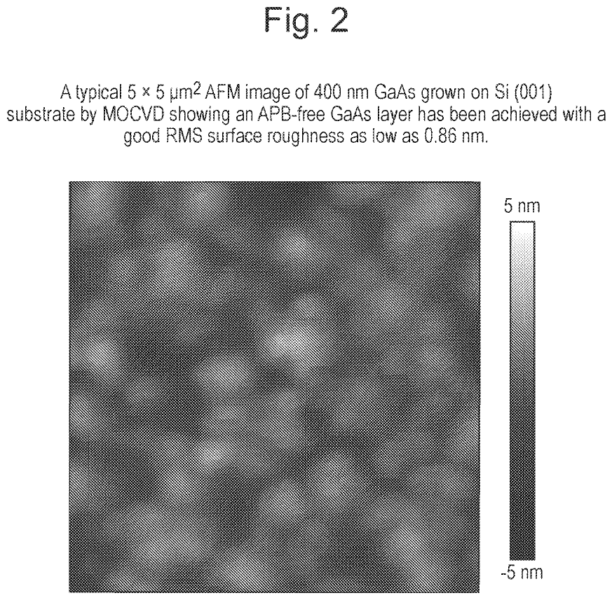

The structural properties of the GaAs film layer grown on Si (001) by MOCVD is characterized by both AFM and TEM measurements. FIG. 2 shows a typical 5×5 pm^{t} AFM image of a 400 nm thick GaAs film layer monolithically grown on 300 mm industry-compatible Si (001) substrate by MOCVD based on the process described above. The measured AFM image indicates that a small RMS surface roughness of 0.86 nm has been achieved, this very small surface roughness is comparable to the best reported values for 1 pm thick GaAs layers grown on Si (001) substrate with 4°-6° offcuts (H. W. Yu, E. Y. Chang, Y.Yamamoto, B.Tillack, W. C. Wang, C. I. Kuo, Y. Y. Wong, and H. Q. Nguyen, Appl.Phys.Lett. 99, 171908 (2011); W. Y. Uen, Z. Y. Li, Y. C. Huang, M. C. Chen, T. N. Yang, S. M. Lan, C. H. Wu, H. F. Hong, and G. C. Chi, J. Cryst. Growth 295, 103 (2006)), despite the fact that only 400 nm GaAs has been deposited on the nominal (001) Si substrate in our structure. In addition, no obvious “V”—groove feature can be observed indicating the realization of APB-free surface due to the formation of perfect doubling of doubling of the height of all silicon surface steps thanks to the effective Si wafer preparation. The observations of APB-free heteroepitaxial GaP on Si (001) by MOCVD have been reported by W. Stolz's group (A. Beyer, I. Nemeth, S. Liebich, J. Ohlmann, W. Stolz, and K. Volz, J. Appl. Phys.109, 083529 (2011)). In their work, to achieve the APB-free GaP nucleation on an exact Si (001) substrate, a homoepitaxial silicon buffer along with a high temperature annealing process is required prior to GaP heteroepitaxy. In comparison, the method presented in the present work is simpler and more compatible with standard industry fabrication processes, since our process does not require the additional Si buffer growth and annealing.

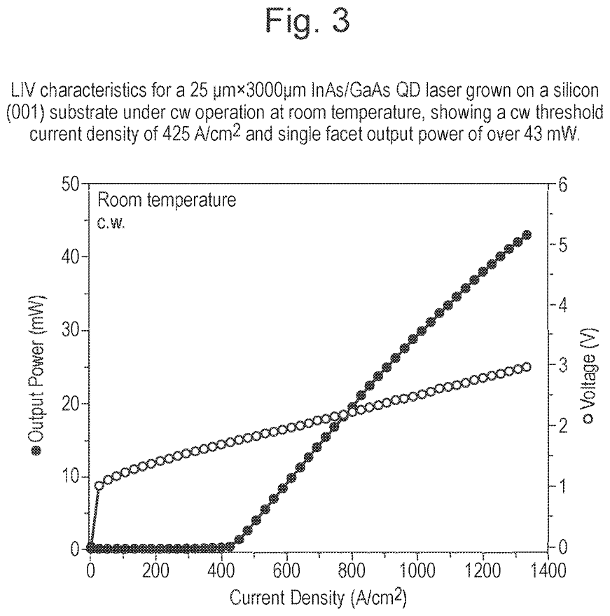

FIG. 3 shows the light-current-voltage (LIV) measurements for an InAs/GaAs QD laser grown on a silicon (001) substrate under cw operation at room temperature. A clear knee behaviour in the LI curve is observed at the lasing Jₜh of 425 A/cm². The single facet output power measured is 43 mW at an injection current density of 1.3 kAJ cm², with no obvious evidence of power saturation up to this current density.

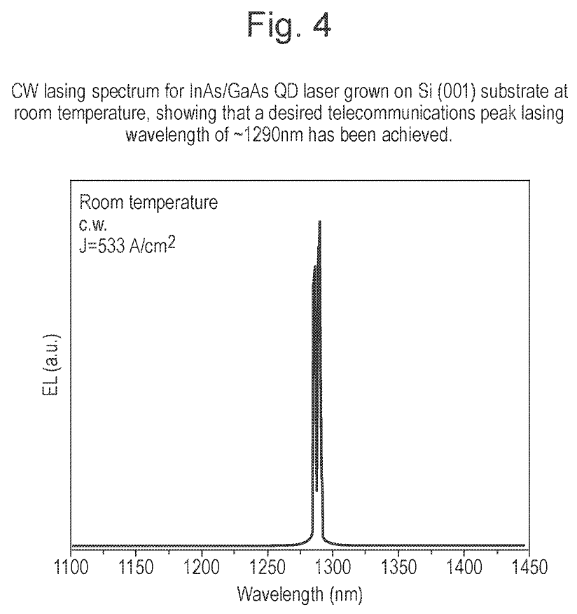

FIG. 4 shows the lasing spectrum at an injection current density of 533 A/cm², in which a lasing peak at 1288 nm is observed.

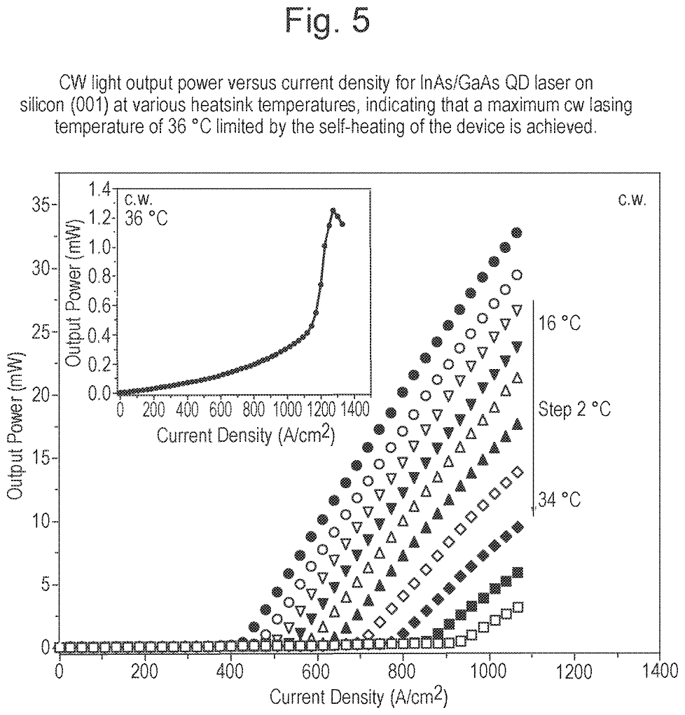

FIG. 5 shows the cw output power for the QD laser grown on Si (001) at various temperatures. The cw lasing in the ground state was maintained until a heatsink temperature of 36° C. due to the self-heating of the device.

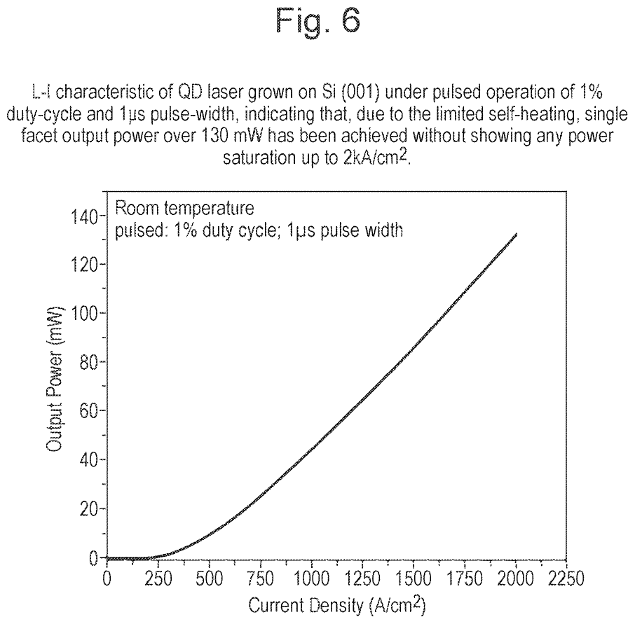

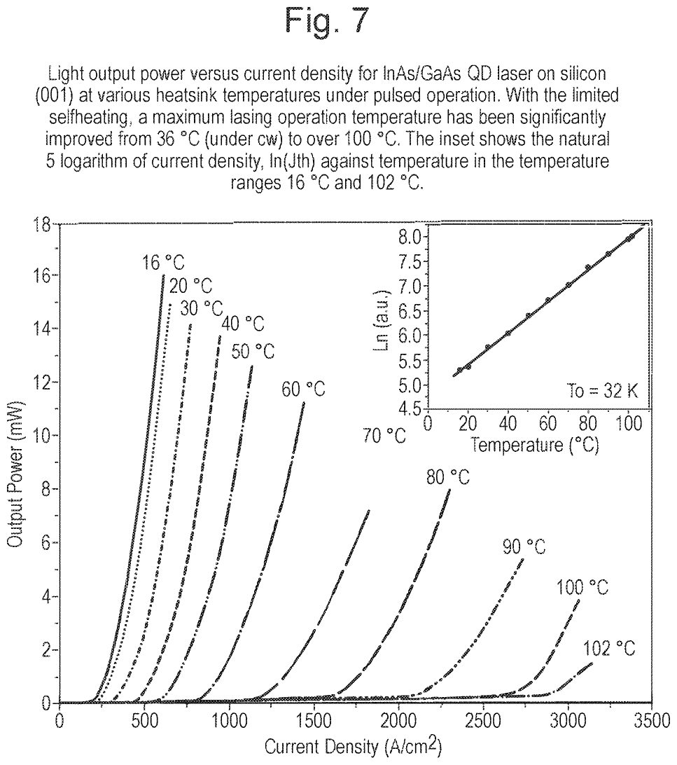

This silicon-based QD laser has also been tested under pulsed operation, and lasing up to 120° C. was demonstrated with an output of over 130 mW at room temperature with limited self-heating as seen in FIG. 6 and FIG. 7. The poor To value of 32K observed here is mainly due to hole excitation out of the lasing state (C. Jin, T. Badcock, H. Liu, K. Groom, R. Royce, D. Mowbray, and M. Hopkinson, “Observation and modelling of a room-temperature negative characteristic temperature 1.3-pm p-type modulation-doped quantum-dot laser,” IEEE J. Quantum Electron. 42(12), 1259-1265 (2006)). It should be mentioned that the active region studied in this work is undoped. Note that p-type modulation doping of the QDs has been well established to increase the value of To, even to To ˜co for GaAs-based InAs QD lasers by suppressing hole excitation (M. Sugawara and M. Usami, “Quantum dot devices: Handling the heat,” Nat. Photonics 3(1), 30-31 (2009)).

These results have demonstrated the use of direct grown GaAs on nominal (001) Si substrates for silicon-based 1.3-pm InAs/GaAs QDs lasers. RT cw lasing at ˜1.3 pm is achieved with threshold current density of 425 A/cm². With limited self-heating, we show significantly improved device performance with lasing operation over 100° C. and output from a single facet exceeding 130 mW at room temperature under pulsed operation, values which are better than conventional values for 1.3-pm InAs/GaAs QD devices grown on Si substrates with a GaP nucleation layer.

### Detailed Methods

Crystal growth. The compound semiconductor layers were grown by solid-source III-V molecular beam epitaxy (MBE). InAs/GaAs QD samples were grown on a GaAs coated silicon piece cut from standard on-axis Si (001) 300 mm substrates with an offcut angle about 0.15° towards the [110] direction. The oxide desorption was performed by thermally heating the GaAs/Si virtual substrate to a temperature of 610° C. in ultra-high vacuum exposed with a high molecular beam flux of arsenic for 8 minutes. The substrate was then cooled down to 590° C. for the growth of a 600-nm GaAs buffer and a 100 nm superlattice consisting of alternating layers of 1 nm Al_{0.4}Ga_{0.6}As and 1 nm GaAs. Five sets of 10-nm Ino.isGao.siAs/10-nm GaAs stained layer superlattices (five periods) followed by 350-nm GaAs were then deposited as dislocation filter layers. Thermal annealing was introduced after growth of the stained layer superlattices and prior to the 350-nm GaAs. Finally, a layer InAs/InGaAs dot-in-a-well (DWELL) laser structure, consisting of 1400 nm Si-doped Al_{0.4}Ga_{0.6}As bottom cladding layer, 50 nm undoped Al_{0.2}Ga_{0.x}As spacer and 70 nm undoped GaAs bottom waveguide layers, five periods of InAs/Ino.isGao.siAs QWELLs, 70 nm undoped GaAs and 50 nm undoped Alo.iGao.sAs spacer top waveguide layers, 1400 nm Be-doped Al_{0.4}Ga_{0.6}As top cladding layer, and finally 300 nm heavily Be-doped GaAs top contact layer. Each period of InAs/Ino.ixGao.xiAs QWELLs consists of 2.7 MLs of InAs quantum dots sandwiched by 2 nm of Ino.isGao.siAs and 6 nm of Ino.i₈Gao.₈₂As. These DWELL lasers were grown at 510° C. The five periods of DWELLs were separated by 45-nm GaAs barriers grown at 580° C. for GaAs.

Device Fabrication'. The Si-based QD laser structure was fabricated into broad-area lasers with varying stripe widths of 25 pm and 50 pm following standard optical lithography and wet chemical etching techniques. The top mesa was etched to about 100 nm above the active region. The top n-contact layer was etched down to the highly n-doped GaAs buffer layer just below the n-type AlGaAs cladding layer. Ti/Pt/Au and Ni/GeAu/Ni/Au were deposited on top of the etch mesa and exposed highly n-doped GaAs buffer layer to form the p- and n-contacts, respectively. After thinning the silicon substrate to 120 pm, the laser bars were cleaved into the desired cavity lengths, which were then mounted on copper heatsinks and gold-wire bonded to enable testing. The final devices described here were 25 pm in width and 3 mm in length, and no facet coatings were applied.

Measurements'. The surface morphology was characterized by a Nanoscope Dimension 3100 SPM atomic force microscopy (AFM) system using a standard tapping mode. The structural properties were investigated by cross-section transmission electron microscopy (TEM) using a JEOL 201 OF field-emission microscope operating at 200 kV. Optical properties were measured by photoluminescence (PL) measurements excited from a 532 nm diode-pumped solid-state laser. Laser device characteristics were measured under both cw and pulsed conditions of Ips pulse-width and 1% duty-cycle.

### Other Embodiments

Although the use of superlattice DFLs has been described above, their number and design may be varied according to the dislocation density at the MOCVD/MBE epitaxy interface layer.

In the earlier described embodiments of the disclosure, the layer that is grown on top of the NL epilayer is GaAs. However, any suitable III-V compound could be used, such as InP, GaSb, GaAs or mixtures of the elements in these compounds. GaN is excluded from the possible III-V compounds because it has a wurtzite crystal structure, so is generally not compatible with the epilayer, which is typically of the zinc blende crystal structure. In contrast, GaAs has a zinc blende crystal structure and a similar lattice constant to AlAs, so the AlAs nucleation layer (epilayer) has close crystallographic properties to GaAs and specifically mitigates the presence of defects at the interface; consequently, active photonic structures grown on top can have enhanced properties.

Optionally, the mean thickness of the NL is at least 2.5 nm. By providing that the mean thickness of the NL is at least 2.5 nm, the prevention of threading dislocations can be improved.

Optionally, the buffer layer of the III-V compound, other than GaP, formed directly on the NL has a mean thickness of at least 100 nm.

Optionally, the silicon substrate has an offcut angle of less than 0.5° towards the [110] direction. Optionally, the silicon substrate has a non-zero offcut angle towards the [110] direction.

The disclosure is not limited to a quantum dot laser on a Si substrate, but could be used for other general semiconductor structures, for example detectors, modulators or other III-V photonic devices on a Si substrate. III-V electronic devices, such as diodes and transistors could also be fabricated with the use of this disclosure. Applications include but are not limited to chip-to-chip optical inter-connects, solar cells, optical fibre communications (light emitters and detectors).

In a method embodying the present disclosure, the NL can be grown at a relatively low temperature, because it is relatively thin. This can be advantageous in lowering the quality of any interfacial defects. The NL can be grown at a temperature below 500° C. A suitable temperature range is from 300° C. to 500° C., and is exemplified in the description above at 400° C.

In the detailed method described above, the crystal growth is by both MOCVD and MBE, but it could also be done by any combination of these techniques or by chemical vapour deposition (CVD) or by other epitaxy techniques.

Semiconductor devices and fabrication methods have been described above with reference to various specific embodiments and examples. However, it is to be understood that the claims below are in no way limited to these specific embodiments and examples.

The foregoing description of some embodiments of the disclosure has been presented for purposes of illustration and description. The description is not intended to be exhaustive or to limit the disclosure to the precise form disclosed, and modifications and variations are possible in light of the above teachings. The specifically described embodiments explain the principles and practical applications to enable one ordinarily skilled in the art to utilize various embodiments and with various modifications as are suited to the particular use contemplated. Various changes, substitutions and alterations can be made hereto without departing from the spirit and scope of the disclosure.

1. A semiconductor device comprising:
(001) silicon substrate with a miscut angle less than 0.5 degrees;
a nucleation layer (NL) comprised of a III-V compound, other than GaP, formed directly on the substrate;
at least one layer of the same III-V compound, other than GaP, formed directly on the NL; and
at least one layer containing III-V compound quantum dots.

2. A semiconductor device according to claim 1, wherein the mean thickness of the NL is less than 100 nm.

3. A semiconductor device according to claim 1, wherein the mean thickness of the NL is less than 50 nm.

4. A semiconductor device according to claim 1, wherein the NL III-V compound layer grown on the substrate is one of a GaAs layer, an la layer or a GaSb layer.

5. A semiconductor device according to claim 1, wherein the NL III-V compound layer has a zinc blende crystal structure.

6. A semiconductor device according to claim 1, which incorporates dislocation filter layers (DFL) on nominal (001).

7. A semiconductor device according to claim 1, which incorporates one or more dislocation filter layers (DFL) based on quantum well super-lattice layers on nominal (001) silicon.

8. A semiconductor device according to claim 1, which incorporates one or more dislocation filter layers (DFL) based on quantum well super-lattice layers (SLSs), wherein each SLS is made of one or more periods of Inₓ [X]₁₋ₓAs/GaAs layers on nominal (001) silicon,
wherein the SLSs comprises a compound of the formula:
Inₓ [X]₁₋ₓAs wherein:
X is at least one group III element other than in;
x is greater than or equal to 0; and
x is less than or equal to 0.5.

9. The device of claim 8, wherein the number of repeats of SLSs is in the range of 3 to 6.

10. The device of claim 8, wherein the number of periods of Inₓ [X]₁₋ₓAs/GaAs is 5.

11. The device of claim 8, wherein X is Ga.

12. The device of claim 8, wherein the thickness of Inₓ[X]₁₋ₓAs is in the range of 8 nm to 11 nm.

13. The device of claim 8, wherein the thickness of GaAs within the Inₓ [X]₁₋ₓ As/GaAs SLS is in the range of 8 nm to 11 nm.

14. The device of claim 8, wherein the thickness of a GaAs spacer layer is in the range of 250 nm to 350 nm.

15. A semiconductor device according to claim 1, wherein one or more epitaxial growth steps are paused and the substrate temperature increased to promote annealing of epitaxial defects for III-V lasers grown on nominal (001) silicon substrates.

16. The device of claim 15, wherein the annealing temperature is in the range of 660° C. to 750° C.

17. The device of claim 15, wherein the annealing time is in the range of 1 min to 10 mins.

18. The device of claim 15, wherein the number of annealing processes is in the range of 1 to 5.

19. A quantum dot laser comprising a semiconductor device according to claim 1.

20. A quantum dot laser according to claim 9, wherein the lasing wavelength is in the range of from 1250 nm to 1350 nm.

21. A quantum dot laser according to claim 19 comprising lnAs/GaAs quantum dot structures.

22. A method of fabricating a semiconductor device comprising:
(001) silicon substrate with a miscut angle less than 0.5 degrees;
epitaxially growing a NL comprised of a III-V compound, other than GaP, formed directly on the substrate;
epitaxially growing at least one layer of the same III-V compound, other than GaP, formed directly on the NL; and
epitaxially growing at least one layer containing III-V compound quantum dots.

23. A method according to claim 22, comprising growing the NL to have a mean thickness of less than 100 nm.

24. A method according to claim 22, wherein the NL is GaAs.
